(19) United States
(12) Patent Application Publication
(10) Pub. No.: US 2023/0109919 A1
(43) Pub. Date: Apr. 13, 2023

(54) Resonant Electromagnetic Sensor and System and Methods to Optimize

(71) Applicant: Kevin D. McGushion, Clearwater, FL (US)

(72) Inventor: Kevin D. McGushion, Clearwater, FL (US)

(21) Appl. No.: 17/913,720

(22) PCT Filed: Mar. 23, 2021
(86) PCT No.: PCT/US21/23767

§ 371 Date: Sep. 22, 2022

Related U.S. Application Data
(60) Provisional application No. 62/993,547, filed on Mar. 23, 2020.

(51) Int. Cl. G01N 27/72

(52) U.S. Cl. CPC G01N 27/72

(57) ABSTRACT

A sensor and/or detector having been optimized to produce a rapid rate of change in capacitive reactance and or inductive reactance such that changes in material composition or signal withing the electromagnetic field of the sensor or detecting means will produce a high rate of change in the output signal of the sensing or detecting means.

### BACKGROUND

The subject of this patent application relates generally to methods, systems, and devices for inspection of materials and or phenomena and or detection of materials and or phenomena by way of an electromagnetic field, in which the capacitive reactance and or inductive reactance of the field may be distorted to provide an optimized signal output.

By way of background, in industry (e.g., construction, medicine, science, communications, etc.) electromagnetic fields are often used to interrogate qualities, features, states, and characteristics of target materials, objects, substances, or signals, collectively, target material/s. The manner in which and the extent to which the electromagnetic field or fields are altered, attenuated, or maintained is indicative of the qualities, features, and characteristics of the target materials being interrogated or monitored by the electromagnetic field. The sensitivity of such a system determines how readily the electromagnetic field is attenuated, modified, or even unaltered by characteristics of target materials.

It is a well-known method in industry that by creating an oscillating electromagnetic field, typically in the form of a sinusoid, in a wound coil of conductive wire, the field can be made to be sensitive to many types of objects and substances placed within its influence. As this electromagnetic field extends into a target material, especially a conductive target material, the field is attenuated, phase shifted, and/or modified by eddy currents produced in the conductor. This method of non-destructive inspection is known as eddy current inspection. This method of inspection is useful in determining material composition and quality and in discovering discontinuities such as cracks, inclusions, or other conditions in metals and conductors in general.

Because this method depends on eddy currents being formed in a conductor, it is not well suited to detecting the presence of, or anomalies within insulators or even partial conductors and composite materials containing characteristics of both conductors and insulators. Further this method is not sensitive to changes in atomic state such as with isotope decomposition or generally radioactive decay and changes in electromagnetic signals.

A common arrangement of an eddy current inspection sensor is known as a reflection type probe. In this configuration a first coil, commonly referred to as a drive coil, is used to excite a second or combination of coils, commonly referred to as a pick-up coil or coils. Through proximity of these coils which may include use of a core type material with desired magnetic permeability, they are electromagnetically coupled. As a target object is placed in proximity of the coupled electromagnetic field, attenuation of that field due to the eddy current affect inducing a phase or amplitude change in the field is manifested in the pick-up coil. However, like the single coil type eddy current sensor described previously this reflection type device is not sensitive to insulators or poor conductors, representing a limitation of these types of devices in the field of nondestructive testing, detection or sensing. This method is not sensitive to changes in atomic state such as with isotope decomposition or generally radioactive decay and changes in electromagnetic signals.

Yet another common method of nondestructive testing is ultrasonic testing where, a frequency ranging from about 0.1 MHz to about 15 MHz is produced in a transducer and caused to propagate into a target material with the aid of a coupling fluid such as water, oil, or various types of gels in order to transfer the waveform from the transducer to the object. As this ultrasonic wave transitions through the target material, transitions in density or other characteristics can be monitored by the fact that these transitions can cause reflections of sound back to the transducer where they can be measured and or timed and or attenuation of the signal evaluated after it passes through an object. Ultrasonic testing can only be used on materials that can conduct ultrasonic frequencies and waveforms, removing an important class of materials from inspection by this means. It is also limited by materials which may have non-solid or porous gaps between them or between the ultrasonic transducer and the material, as ultrasonic waves may not be transmitted over these gaps or porous materials. This method is not sensitive to changes in atomic state such as with isotope decomposition or generally radioactive decay and changes in electromagnetic signals

What is needed in the field of non-destructive inspection and generally sensing and detecting is a sensor or detector that is responsive to conductors and insulators alike as well as materials that exhibit qualities of both conductors and insulators. What is also needed is a sensor or detector that is sensitive to changes in atomic state such as with isotope decomposition or generally radioactive decay and changes in electromagnetic signals which may be in proximity to the sensor or remote from it. What is also needed is a sensing means that can both transition over and inspect gaps between materials or between materials and the sensor, as well as inspect without the need for a coupling fluid.

### SUMMARY

The present sensor or detector disclosed herein is configured to increase sensitivity of an electromagnetic field to changes in target materials, objects, substances and signals by optimizing the manner in which changes in capacitive reactance and or inductive reactance respond while at, approaching, leaving, or in proximity to a resonant electromagnetic field which may be generated by one or more conductive coils and received by one or more conductive coils.

The sensor or detector is comprised of a first coil or multiple coils and a second coil or multiple coils where the first coil is set to resonate, by way of inducing an EMF in the coil, producing an oscillating electromagnetic field, at or in proximity to its resonant frequency which is also at or in proximity to the resonant frequency of the second coil, causing energy to be transferred from the first coil to the second coil in a manner that is optimized to yield a desired sensitivity in the electromagnetic field to target materials, objects or signals placed within the influence of the electromagnetic field. In this optimized state, the system, which is a highly tuned LRC (inductance, resistance, and capacitance) circuit, is sensitive to changes in capacitive reactance and inductive reactance and as such can measure characteristics of insulators and conductors. In this highly tuned state, the sensor or detector is also responsive to changes in the state of radio isotopes, as well as electromagnetic signals which may be remote to the sensor or separated from the sensor by other substances or materials. A further optimization of this sensor is caused when the capacitive and inductive fields and or capacitive or inductive coupling between the first coil or coils and the second coil or coils can be modified such that rapid changes in capacitive reactance and or inductive reactance are produced which can be made sensitive to small changes in a target material and or signal within the influence of the electromagnetic field created by the sensor or detector.

Other features and advantages of aspects of the present invention will become apparent from the following more detailed description, taken in conjunction with the accompanying drawings, which illustrate, by way of example, the principles of aspects of the invention.

### BRIEF DESCRIPTION OF THE DRAWINGS

The accompanying drawings illustrate aspects of at least one non-limiting embodiment of the present invention. In such drawings:

FIG. 1 is a schematic diagram of a resonant LRC circuit incorporating two coils, a transmit coil and a receive coil;

FIG. 2 is an isometric view of a transmit coil and a receive coil such as the one shown in FIG. 1,

FIG. 3 is a top view of a transmit and receive coil such as the one shown in FIG. 2;

FIG. 4 is a sectioned side view of a transmit and receive coil such as the one shown in FIG. 2;

FIG. 5 is a frequency response graph containing the curves of various sensors;

FIG. 6 is a frequency response graph containing the curves of various other sensors;

FIG. 7 is a frequency response graph showing a unmodified and a modified electromagnet field;

FIG. 8 is a frequency response graph showing reactance and resonance;

FIG. 9 is a frequency response graph showing modified reactance;

FIG. 10 is an isometric view of a sensor with a transmit coil and a receive coil placed in various locations;

FIG. 11 shows a frequency response graph of the receive coil output when placed at various locations according to FIG. 10;

FIG. 12 is a side section view of the sensor of FIG. 10 with receive coil in position E;

FIG. 13 is a side section view of a sensor being set at an angle;

FIG. 14 is a sensor having two receive coils; and

FIG. 15 is a sensor having two receive coils and being set at an angle.

The above-described drawing figures illustrate aspects of the invention in at least one of its exemplary embodiments, which are further defined in detail in the following description. Features, elements, and aspects of the invention that are referenced by the same numerals in different figures represent the same, equivalent, or similar features, elements, or aspects, in accordance with one or more embodiments.

### DETAILED DESCRIPTION

The detailed descriptions set forth below in connection with the appended drawings are intended as a description of embodiments of the invention, and is not intended to represent the only forms in which the present invention may be constructed and/or utilized. The descriptions set forth the structure and the sequence of steps for constructing and operating the invention in connection with the illustrated embodiments. It is to be understood, however, that the same or equivalent structures and steps may be accomplished by different embodiments that are also intended to be encompassed within the spirit and scope of the invention.

In one or more embodiments, it is a goal in the present disclosure to increase the sensitivity of an electromagnetic field to changes in target materials, objects, substances, and signals by optimizing the manner in which changes in capacitive reactance and inductive reactance can be modified while at, approaching, leaving, or in proximity to a resonant electromagnetic field which may be generated by one or more conductive coils and received by one or more conductive coils.

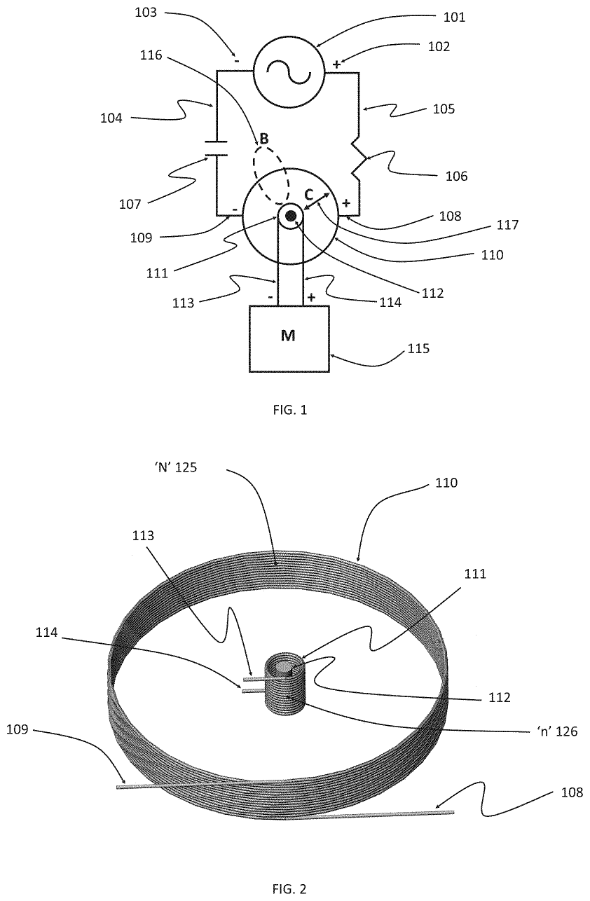

Looking first at FIG. 1, where 101 is a source of oscillating EMF (electromotive force) with relative positive 102 and negative 103 leads, which may periodically oscillate, generally in the form of a sinusoid and reverse polarity with each other at a rate which matches a desired frequency. It is understood that this oscillation may not result in reversal of polarity if the voltage is kept positive at both leads and the EMF is oscillated from a lower positive voltage to a higher positive voltage and from a higher positive voltage to a lower positive voltage or the voltage could be kept negative at both leads and the EMF oscillated from a lower negative voltage to a higher negative voltage and from a higher negative voltage to a lower negative voltage. Lead 103 attaches to a conductive wire 104 in turn connecting to capacitor 107 and then to lead 109 which is one leg of transmit coil 110. Additionally, lead 102 attaches to conductive wire 105, in turn connecting to resistor 106 and then to lead 108 which is another leg of a transmit coil 110. In this figure, capacitor 107 and resistor 106 may represent the parasitic capacitance and resistance of the transmit coil 110, having inductance as well and or it may represent the sum of capacitances and resistances which may include the addition of components such as capacitors, resistors and inductors in order to achieve senor output optimization. The oscillating EMF 101 in turn creates an oscillating magnetic B field 116 and capacitive charge C 117 between receive coil 111 and transmit coil 110 such that energy is transfer from transmit coil 110 to receive coil 111 by way of the magnetic B field 116 and capacitive charge 117. Receive coil 111 being within the influence of magnetic B field 116 and capacitive charge 117 creates its own EMF in response to the induced field by transmit coil 110. Optional magnetic permeable core material 112 may be added to the circuit to further focus magnetic B field 116. The EMF created by receive coil 111 is conducted through wires 113 and 114 to a monitoring means 115 which may be an oscilloscope, a peak detector, a rectifier, a current detector, an impedance detector, phase angle detector, gain detector, spectrum analyzer, network analyzer or any means of detecting the EMF generated by receive coil 111. This monitoring means 115 may have a display conveying values associated with the EMF created by receive coil 111 to an operator or it may be attached to a computing means for further processing and or display.

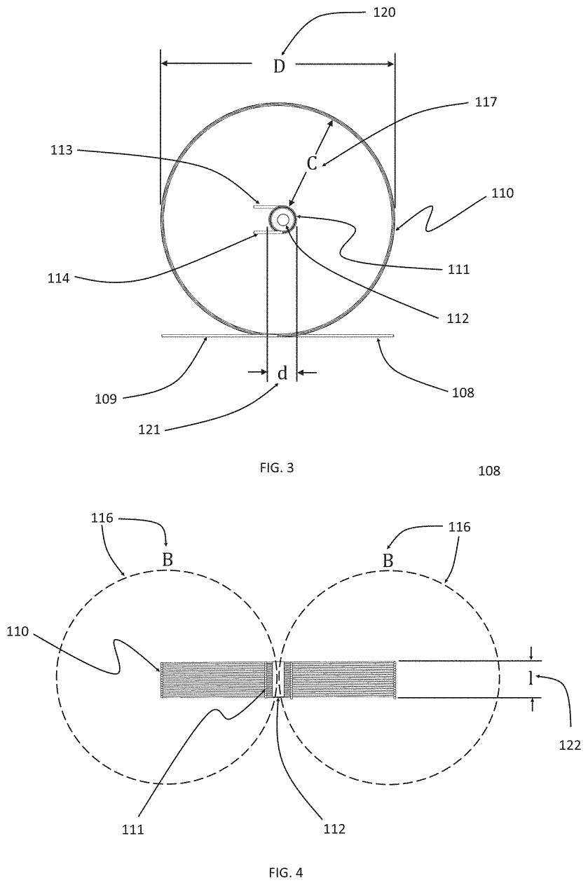

Looking at FIGS. 2, 3 and 4 which shows one physical arrangement of transmit coil 110 and receive coil 111, with receive coil 111 having been interposed within the coils of transmit coil 110 and with an optional core being interposed within receive coil 112. This core, generally of a magnetically permeable material but not limited to a specific permeability as other characteristics may be desirable from a core material to suit the function of the sensor. FIG. 2 shows the transmit coil 110 having a number of windings ‘N’ 125, which is one factor in determining the frequency at which the transmit coil 110 will resonate. Likewise, in FIG. 2, receive coil 111 also has a number of windings ‘n’ 126 which is one factor in determining the frequency at which the receive coil with resonate. Optional core material 112 also being a factor in determining the frequency at which coils 110 and 111 will resonate. FIG. 3 shows diameter ‘D’ 120 which also affects the frequency at which transmit coil 110 will resonate and diameter ‘d’ 121 which also affects the frequency at which receive coil 111 will resonate. FIG. 3 also shows capacitance ‘C’ 117 which exists between the charged transmit coil 110 and receive coil 111. Capacitance 117 can vary relative to a number of factors such as relative charge between the transmit and receive coils, the difference between transmit coil diameter 120 and receive diameter 121, coil height ‘I’ 122 and materials which may be present within or around the sensor assembly. FIG. 4 shows height ‘I’ 122 of the transmit coil 110 and receive coil 111. In this example the height of the transmit coil and receive coil are shown as equal however, they may differ in height depending on the desired output and function of the sensor. Additionally, height ‘I’ 122 of the optional core 112 may also be equal to that of the transmit and or receive coil or different depending on the desired output and function of the sensor and the manner in which the core material 112 is placed within the receive coil may also be varied to achieve a desired output.

FIG. 5 is an example of a frequency response graph, where the ‘X’ axis 201 is graduated in kHz (kilohertz) with values ranging from 200 kHz, 202 to 700 kHz, 203. The ‘Y’ axis of this graph is graduated in output volts 200 and varies from 0 volts, 204 to 4.5 volts, 205. This graph is meant only as an example of one embodiment and other graphs can vary in any frequency range or increment or any voltage range or increment and the units may be other than voltage and KHz. Any scale or unit may be used which may be suitable to convey the characteristics of the sensor. This graph conveys the output of receive coil 111 when in communication with transmit coil 110 and placed in an arrangement such as the one outlined in FIG. 1 where, the rectified output voltage 200 of receive coil 111 is observed by monitoring device 115 and the data of which is represented in a frequency response graph such as the one shown in FIG. 5. In this case the ‘Y’ axis output voltage scale 200 represents the rectified voltage output of each of the three sensor configuration's receive coils 111. In the three different sensor arrangements, the transmit coil 110 of each sensor arrangement varies from a higher number of turns ‘N’ 125 on sensor curve 208 to a lower number of turns ‘N’ 125 on sensor curve 207 and an even lower number of turns ‘N’ on sensor curve 206. It can be seen that with a higher number of transmit coil turns ‘N’ on sensor curve 208, that the resonant frequency peak 209 of the transmit coil is lower relative to the other two sensors 207 and 206. As the number of transmit coil turns ‘N’ reduces in sensor curve 207, the resonant frequency peak 210 can be seen to increase in both frequency and output voltage 200 amplitude. Still further reducing the number of transmit coil turns ‘N’ in sensor curve 206 the resonant frequency peak 211 of the transmit coil can be seen to move to higher frequencies as well as a higher output voltage 200 amplitude. Beginning with sensor curve 208 where the transmit coil 110 appears to resonate 209 at just below 250 kHz and moving further to the right to higher frequencies along sensor curve 208, there is a dip in output volts 200 from about 300 kHz to 500 kHz. Moving further to the right toward yet higher frequencies it can be seen that there is a rapid rise 218 in output volts 200 which continues until it reaches its receive coil 111 resonant peak 212 for that sensor. Receive coil resonant peak 212 corresponds to a certain number of receive coil turns ‘n’ which is coincident with a resonant frequency 212 of just below 600 KHz. Still further to the right and to higher frequencies of resonant peak 212 is a high negative slope region 215 where there is a sudden loss of output volts 200. Likewise, it can be seen in sensor curve 207, having a lower number of transmit coil turns ‘N’ than sensor curve 208, that its transmit coil resonant peak 210 is higher in frequency 201 and output volts 200. Moving further to the right toward higher frequencies there is a dip in output volts 200 between frequencies 201 of about 350 kHz and 500 kHz.

Moving toward yet higher frequencies 201 on sensor curve 207 there begins a rapid rise 219 to receive coil resonant peak 213 at about 600 kHz. Moving still further to the right toward higher frequencies 201 there is a sudden loss of output volts 200. The same characteristic shape occurs for sensor curve 206 where is transmit coil resonant peak 211 is at a higher frequency than that of resonant peak 210. Moving to the right toward higher frequencies 201 there is a dip in output volts 200 then a rapid rise 220 in output volts until receive coil resonant peak 214 is reached, corresponding to just over 600 kHz. In this example it can be seen that as the resonant frequency of the transmit coil is moved closer to the resonant frequency of the receive coil both the output volts 200 of the transmit coil 110 and receive coil 111 increases. This increase is due to an increase in efficiency of energy transfer between the transmit coil 110 and receive coil 111 as their respective resonant frequencies become closer. This process of reducing transmit coil turns ‘N’ to modify resonant frequency in order to move closer to, or to match, or to even go beyond the resonant frequency of the receive coil can be continued depending on the desired output response relative to material or signal placed within the sensors electromagnetic field or to achieve any other characteristic desired in the sensor.

In FIG. 5 it can be seen that to the right of the receive coil resonant peaks 212, 213 and 214, each sensor curve exhibits a high negative slope, high slope or high rate of change condition 215, 216 and 217 causing each of the sensor curves to suddenly reduce in output voltage. This high slope region causes a large output voltage 200 change relative to a small change in frequency 201. These high slope regions 215, 216 and 217 are sensitive to both conductive and nonconductive material changes and to inductive and capacitive changes. It is also sensitive to changes in state of other electromagnetic signals, and it is sensitive to changes in and differences in radio isotopes. In the example of FIG. 5 the receive coil 111 used was the same for all three sensor curves and with the same number of turns ‘n’ 126. However, receive coil 111 can be of any configuration which produces a desired output and or high slope configuration. Likewise, the transmit coil 110 can be of any configuration which produces a desired output and or high slope configuration.

It is further understood that while output volts 200 is displayed in this frequency response graph any of a number of characteristics of the sensor may be monitored, displayed, or otherwise used including current, phase, gain, impedance, capacitance, resistance, sievert, curie or any type of signal unit of measure indicative of the characteristics of the sensor. Also, in this sensor arrangement a certain diameter ‘D’ 120 of the transmit coil was used in conjunction with a certain diameter ‘d’ 121 of the receive coil. It is understood that any of a number of diameters could be used in order to produce a desired sensor output characteristic. A diameter ‘D’ 120 of the transmit coil 110 may be larger relative to diameter ‘d’ 121 of the receive coil 111 or diameter ‘D’ 120 may be close to the diameter ‘d’ 121 of the receive coil 111. Diameters, coil turns, coil height and any configuration in circuitry, construction or implementation of the sensor which produces a sensitive high slope or characteristic which is sensitive to changes of or in material, signal or state of objects or energy within the influence of the sensors electromagnetic field may be used. While the high downward slope region 215, 216 and 217 produces the highest output volts 200 change relative to frequency change, other regions of the sensor curve may produce a desired output. One such desirable region or point may be the resonant peaks 212, 213, and 214 or the upwardly sloping regions of 218, 219 and 220. Indeed, any region of the sensor curve may be used to produce a desired output and at any frequency.

It is understood that not only the number of turns ‘N’ of the transmit coil may be altered but the number of turns ‘n’ of the receive coil may also be altered in order to achieve a desired output but also any portion of the configuration including physical characteristics of both the transmit and receive coils, their physical proximity to one another and the circuit to which they are connected may be altered and or adjusted to achieve a desired slope, sensitivity, or output relative to materials, signals or objects placed within the influence of its electromagnetic field.

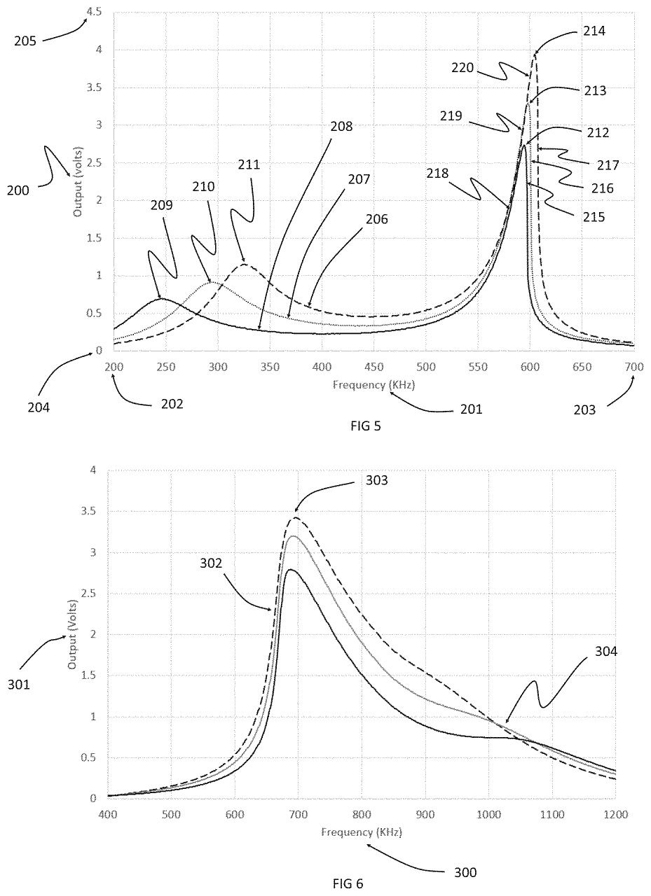

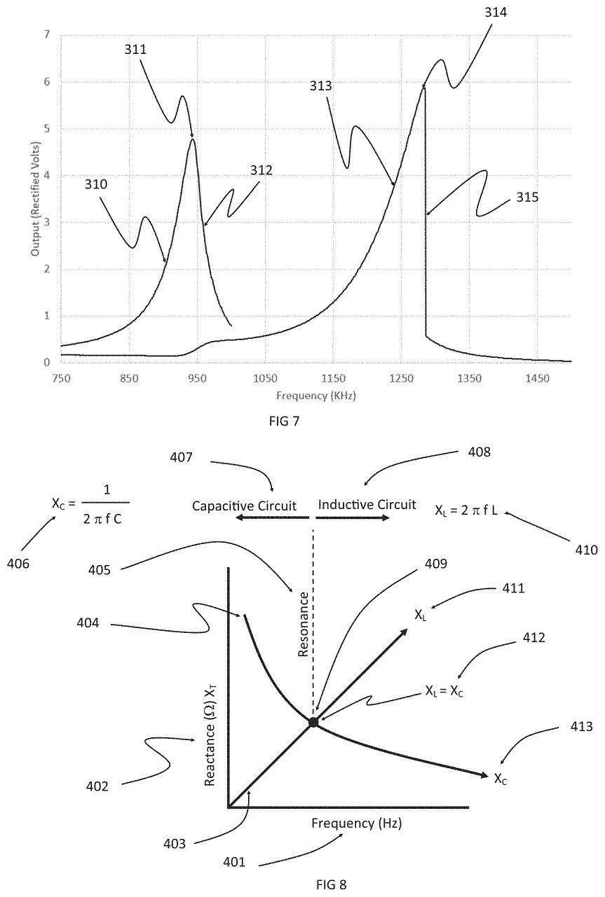

Looking now at FIG. 6, what is shown is a frequency response graph with again the ‘X’ axis 300 displaying frequency in kHz and the ‘Y’ Axis 301 displaying output volts. In this graph the sensor curves show a high positive slope region 302 now to the left of the receive coil resonant peaks 303 and with the transmit coil resonant peaks 304 being instead to the right and at higher frequencies relative to the receive coil resonant peaks 303. In this graph as in the graph of the high slope region 215, 216 and 217 of FIG. 5, the high slope region 302 is sensitive to changes in capacitance and inductance as well as other phenomena. This reversal of slope region may be realized by simply shifting the resonant frequency of the transmit coil to frequencies above the resonant frequency of the receive coil or by changing physical features of the coil or coils used such as diameter ‘D’ 120, or diameter ‘d’ 121 or coil length ‘I’ 122 or the number of turns in the transmit coil or receive coil or by changing or removing the core 112 material or size or by placing material within the sensor configuration or by altering the circuit to which the sensor is connected. Any of a number of design features may be changed to yield a desired output characteristic or characteristics.

Looking at FIG. 7, what is shown is a comparison of an un-optimized frequency response curves 311 and optimized frequency response curve 314. In the example of sensor curve 311 what is shown is what could be expected from the output voltage when the transmit coil, receive coil and or circuitry are un-optimized. In the example of sensor curve 311, there is a gradual slope 310 up to a resonant peak 311 and a corresponding downward slope 312 of the output voltage of this sensor configuration. While portions of this curve may be sensitive to certain changes, such as conductivity, it is not sensitive to changes in capacitance and small signal changes or other phenomena which may have an extremely small effect on the sensor or its frequency or other characteristics. Sensor curve 314 is an example of a highly optimized configuration where the slope region 315 is extremely steep and is highly sensitive to extremely small changes in state of material, signals, radio isotopes and other phenomena. An interesting feature and hence an object of this application is the sudden change in slope or rate of change of sensor curve 314 where, to the left and at lower frequencies of the resonant peak sensor curve slope 313 appears quite ordinary when compared to the un-optimized sensor output 311. As the sensor output approaches its resonant peak 314 again the output is relatively ordinary when compared to the un-optimized sensor output 311. However, as the sensor output exits its resonant peak 314, there is an extremely sudden downward slope or rate of change in output volts relative to frequency where, an extremely small change in frequency corresponds to a very large change in output voltage. The high slope region 315 also has the benefit of creating a high gain output voltage relative to a low frequency change without increasing noise or the signal to noise ratio (SNR). This is an important characteristic of this high slope region of the sensor as in industry, science, medicine and signal processing unwanted noise is often the result of high gain applications such as may be expected to be used in the detection of small anomalies or signals.

Looking at FIG. 8 what is shown is a frequency response graph where the ‘X’ axis 401 is displayed in frequency Hz, and the ‘Y’ axis 402 is displayed in reactance ohms. Briefly, reactance is the nonresistive component of impedance in an AC circuit, arising from the effect of inductance or capacitance or both and causing the current to be out of phase with the electromotive force inducing it. Total impedance Z in a circuit in ohms is a combination of resistance R and the collective reactance's associate with capacitance and inductance and is given by the equation:

Z=\sqrt{R²+(X_{L}−X_{C})²}

Where: Z is the total impedance of a circuit or sensor. R is the ‘real’ component of resistance in ohms of the circuit and X_{L} is inductive reactance and X_{C} is capacitive reactance. X_{L} and X_{C} are the imaginary components of resistance, added together they represent total reactance Xₜ, due to frequency which is given by the following equation.

X_{T}=X_{L}+X_{C}

In an LRC circuit, the resonant frequency peak is reached when the imaginary components of resistance X_{C} and X_{L} are equal and cancel each other out. At this frequency resonance is achieved and the output volts amplitude reaches its highest point because the real component R is the only resistance remaining in the circuit.

Looking again at FIG. 8, what can be seen is X_{C} 413 which is given by the equation 406:

$${X}_{C} = \frac{1}{2 π fC}$$

Where: f is frequency and C is capacitance and X_{L}, 411 is given by the equation 410:

X_{L}=2πfL

Where L is inductance.

FIG. 8 is the sort of graph that could be expected in an un-optimized sensor configuration where, the curve 404 representing capacitive reactance X_{C} 413 curves downward in reactance 202 as frequency 401 increases according to equation 406 and where curve 403, representing inductive reactance X_{L}, 411 moves linearly upward in reactance 402 as frequency 401 increases. The frequency at which these two curvilinear plots intersect is resonance 405 which corresponds to its resonant frequency 409 where, X_{L}, 411 and X_{C} 413 are equal and opposite, thus canceling out. At this resonant frequency 409 the circuit and or sensor circuit is in resonance 405 and as the real component R is the only resistance remaining in the circuit the output volts of the circuit is at maximum constituting the peaks shown in FIGS. 5, 6 and 7. To the left and at lower frequencies from resonance 405 the circuit is a more capacitive circuit 407 and to the right and at higher frequencies from resonance 405 the circuit is a more inductive circuit 408.

Looking now at FIG. 9, the frequency response curve of FIG. 8 has been modified to reflect changes in X_{L}, 411 and X_{C} 413 which create the frequency response curves of FIGS. 5, 6 and 7. It can be seen in FIG. 9 that three curves are represented for X_{C} 413, they are curve 450 (dots) 404 (solid) and 451 (dashed). Each of these capacitive reactance curves represent a potential path for X_{C} as the sensor circuit is in either an optimized or un-optimized state. For example, reactance curve 451 represents the sort of high slop condition that exists in X_{C} in order to produce a high slope output to the left of resonance 409. To the left of resonance, capacitive reactance curve 451 has a high slope which will produce a high slope in the frequency response curve such as seen in FIG. 6. Likewise, to the right of resonance, reactance curve 451 has a high slope which will produce a high slope in the frequency response curve such as seen in FIG. 5 or in example 314 of FIG. 7. Slopes which are more gradual may be represented by reactance curves 404 or 450 when approaching or exiting resonance. Capacitive reactance curve tails 453 and 452 show examples of how the capacitive reactance curve may slope as they exit resonance. While the three reactance curves in FIG. 9 represent possible paths for capacitive reactance X_{C} it is understood that any state in between the states or above or below the states shown in FIG. 9 may be possible and depend on the desired output of the sensor and the optimization configuration selected. It is also understood that combinations of capacitive reactance X_{C} may be possible where to the left of resonance high or low slopes may be desired or to the right of resonance, high or low slopes may be desired.

While FIG. 9 focuses on the modification of slope associated with capacitive reactance X_{C}, it is understood that inductive reactance X_{L}, may also be modified for high and or low slope conditions either to the right or left of resonance and that any modified inductive reactance may be combined with any capacitive reactance for desired output.

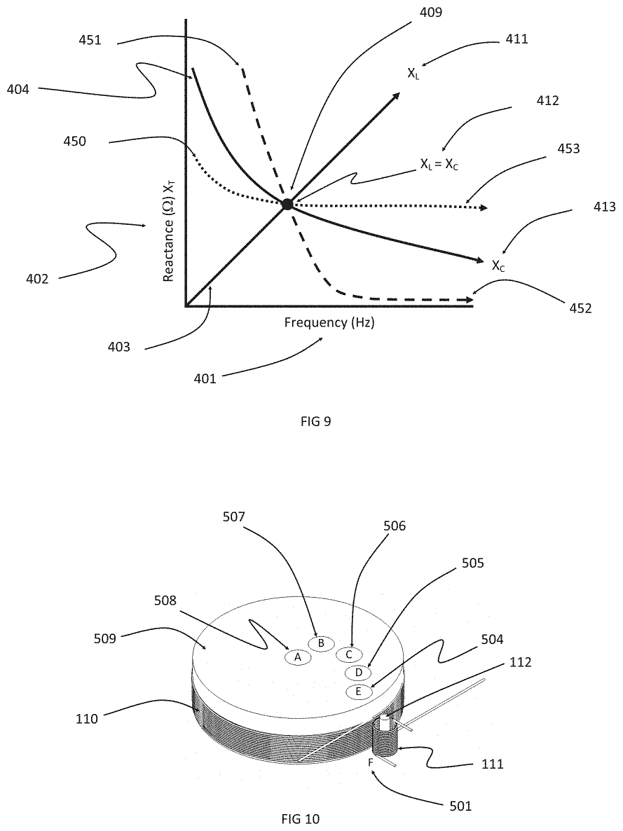

FIG. 10 shows an additional optimization which may optionally be made to the sensor in order to improve output volts or signal, slope configuration of the sensor curve, better resolution of materials, objects or states being imaged or any combination of these. In FIG. 10 sensor housing 509 holds the sensor assembly and is made of material which suits the desired output of the sensor. Transmit coil 110 is wrapped around the exterior portion of sensor housing 509 and holes A 508, B 507, C 506, D 505, and E 504, as well as location F 501, all represent possible positions for receive coil 111 and optional core material 501 to be located. It is understood that while these locations are discrete, that any location between these locations is possible and locations outside what is shown and remote to the transmit coil may also be possible. In FIG. 10 receive coil 111 and optional core material 112 may be placed in any of the locations 501, 504, 505, 506, 507 and 508 provided.

FIG. 11 shows the output volts of the sensor assembly of FIG. 10 when the receive coil 111 is placed in one of the several locations 501, 504, 505, 506, 507 and 508 and the output response curves of these positions respectively 510, 511, 512, 513, 514 and 515. It is understood that more than one receive coil may be used in more than one location at a time in order to achieve a desired sensor output. In the curves of FIG. 11 it can be seen that the degree of slope in each of the six locations changes slightly but that the output volts amplitude changes more dramatically, with the maximum output volts being coincident with location E 504 and corresponding with output curve 511. This location represents the outer most location of the receive coil 111 where it is still resident within the inside diameter of transmit coil 110. At this location the maximum output signal can be achieved. This location has the added benefit of being able to resolve small anomalies because of a local distortion of the magnetic B field and capacitive C field.

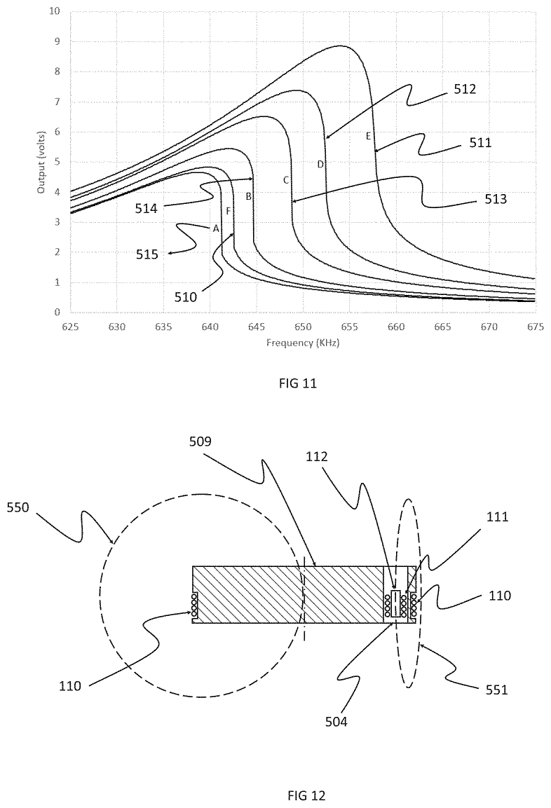

FIG. 12 shows a sectioned side view of FIG. 10 with the receive coil 111 and optional core 112 being located at optimized position E 504. It can be seen that when the receive coil 111 and core 112 are placed in this location the magnetic B field 551 is distorted by the presence of the core and receive coil. This distorted B field 551 is contrasted by the undistorted B field 550 on the side opposite of the sensor configuration. This distortion of B field 551 has the effect of localizing the field around the receive coil 111 so that smaller anomalies present in materials being imaged are evident. This in contrast to B field 550 which if the receive coil 111 were placed in the center of the transmit coil 110 at location 508 the signal output would represent an average of the features within the magnetic B field 550.

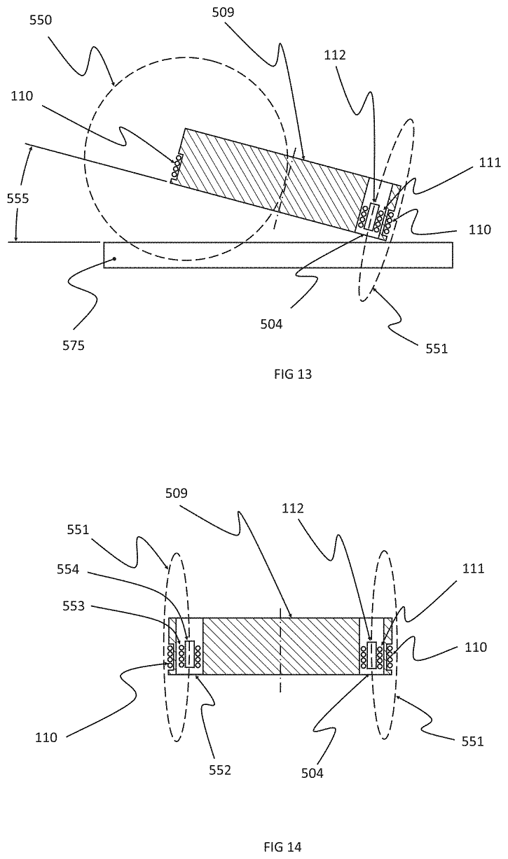

FIG. 13 shows still another optimization of the sensor configuration as described in FIG. 12 where the sensor assembly is rotated in the direction of the receive coil at angle 555, such that output signal is further increased and sensitivity to small changes, anomalies or features is still further enhanced and are detectable by the sensor. The angle 555 may be any angle which causes the sensor assembly to produce a desired output.

FIG. 14 shows still another optimization of the sensor configuration where 2 receive coils 111 and 553 with optional core materials 112 and 554 and in positions 504 and 552 in which they are located inside transmit coil 110 and where they may be located in opposition to one another such that they are 180 degrees apart, as shown in FIG. 14. In this orientation, they would both receive substantially the same signal if placed over the same material and they would receive a different signal if they were each placed over different materials or material which had differing characteristics. These receive coils 111 and 553 may be placed in any location inside or outside the transmit coil 110 diameter and oriented in any manner angularly relative to one another and or the transmit coil in order to achieve a desired signal output or result. Further, these coils may be connected to one another either directly or indirectly after first having passed through circuitry and or computation such that common mode signal or noise is reduced or eliminated and the signal accounting for the difference between the coils is enhanced. These two coils or any number of coils may be connected in any manner which further optimizes the output of the sensor.

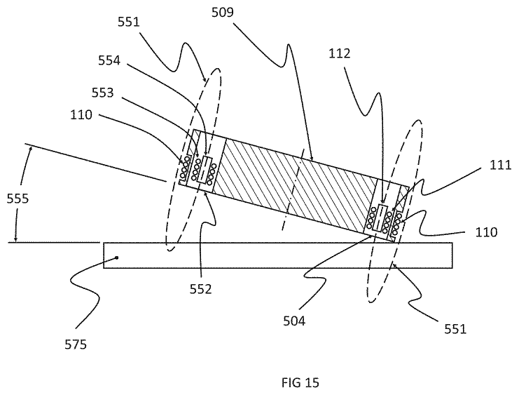

FIG. 15 shows yet another optimization of the sensor of FIG. 14 where the sensor assembly is rotated at angle 555 relative to the target material 575 such that output is further increased at receive coil 111 and consisting of signal associated with target material 575 and receive coil 553 having an output voltage that is substantially devoid of the effects of target material 575. These receive coils 111 and 553 may be placed in any location inside or outside the transmit coil 110 diameter and oriented in any manner in order to achieve a desired signal or result. Further, these coils may be connected to one another either directly or indirectly after first having passed through circuitry and or computation such that common mode signal or noise is reduced or eliminated and the signal accounting for the difference between the coils is enhanced. These two or any number of coils may be connected in any manner which further optimizes the output of the sensor.

Aspects of the present specification may also be described as follows:

1. A method of optimizing the responsiveness of a sensor or detector for interrogating a target material, the method comprising providing a transmit coil in communication with a receive coil, the transmit coil configured to emit an oscillating electromagnetic field and the receive coil receiving the electromagnetic field; and adjusting the slope or rate of change of the capacitive reactance of the sensor circuit such that high rates of change in output signal of the receive coil is produced in response to differences in a target material.
2. The method of optimizing of embodiment 1 further comprising the steps of placing the receive coil in a location relative to a transmit coil optimizing the output signal.
3. The method of optimizing of embodiments 1 and/or 2 further comprising the steps of inducing an angle in the sensor relative to the target material, optimizing the output signal.
4. The method of optimizing of one or more of the embodiments 1-3 further comprising the steps of adding a second receive coil and allowing the signals of the receive coils to be combined, optimizing the output signal.
5. The method of optimizing of one or more of the embodiments 1-4 further comprising the steps of inducing an angle in the sensor relative to the target material, optimizing the output signal.
6. A method of optimizing the responsiveness of a sensor or detector for interrogating a target material, the method comprising providing a transmit coil in communication with a receive coil, the transmit coil configured to emit an oscillating electromagnetic field and the receive coil receiving the electromagnetic field; and adjusting the slope or rate of change of the inductive reactance of the sensor circuit such that high rates of change in output signal of the receive coil is produced in response to differences in a target material.
7. The method of optimizing of embodiment 6 further comprising the steps of placing the receive coil in a location relative to a transmit coil optimizing the output signal.
8. The method of optimizing of embodiments 6 and/or 7 further comprising the steps of inducing an angle in the sensor relative to the target material, optimizing the output signal.
9. The method of optimizing of one or more of the embodiments 6-8 further comprising the steps of adding a second receive coil and allowing the signals of the receive coils to be combined, optimizing the output signal.
10. The method of optimizing of one or more of the embodiments 6-9 further comprising the steps of inducing an angle in the sensor relative to the target material, optimizing the output signal.
11. A method of optimizing the responsiveness of a sensor or detector for interrogating a target material, the method comprising providing a transmit coil in communication with a receive coil, the transmit coil configured to emit an oscillating electromagnetic field and the receive coil receiving the electromagnetic field; and adjusting the slope or rate of change of the capacitive reactance and the inductive reactance of the sensor circuit such that high rates of change in output signal of the receive coil is produced in response to differences in a target material.
12. The method of optimizing a sensor of embodiment 11 further comprising the steps of placing the receive coil in a location relative to a transmit coil optimizing the output signal.
13. The method of optimizing of embodiments 11 and/or 12 further comprising the steps of inducing an angle in the sensor relative to the target material, optimizing the output signal.
14. The method of optimizing of one or more of embodiments 11-13 further comprising the steps of adding a second receive coil and allowing the signals of the receive coils to be combined, optimizing the output signal.
15. The method of optimizing of one or more of embodiments 11-14 further comprising the steps of inducing an angle in the sensor relative to the target material, optimizing the output signal.

In closing, it is to be understood that, although aspects of the present specification are highlighted by referring to specific embodiments, one skilled in the art will readily appreciate that these disclosed embodiments are only illustrative of the principles of the subject matter disclosed herein. The specific embodiments are not intended to be exhaustive or to limit the invention to the precise forms disclosed. Therefore, it should be understood that the disclosed subject matter is in no way limited to a particular compound, composition, article, apparatus, methodology, protocol, and/or reagent, etc., described herein, unless expressly stated as such. In addition, those of ordinary skill in the art will recognize that certain changes, modifications, permutations, alterations, additions, subtractions and sub-combinations thereof can be made in accordance with the teachings herein without departing from the spirit of the present specification. It is therefore intended that the scope of the invention is not to be limited by this detailed description. Furthermore, it is intended that the following appended claims and claims hereafter introduced are interpreted to include all such changes, modifications, permutations, alterations, additions, subtractions and sub-combinations as are within their true spirit and scope.

Certain embodiments of the present invention are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the present invention to be practiced otherwise than specifically described herein. Accordingly, this invention includes all modifications and equivalents of the subject matter recited in the claims appended hereto as permitted by applicable law. Moreover, any combination of the above-described embodiments in all possible variations thereof is encompassed by the invention unless otherwise indicated herein or otherwise clearly contradicted by context.

Groupings of alternative embodiments, elements, or steps of the present invention are not to be construed as limitations. Each group member may be referred to and claimed individually or in any combination with other group members disclosed herein. It is anticipated that one or more members of a group may be included in, or deleted from, a group for reasons of convenience and/or patentability. When any such inclusion or deletion occurs, the specification is deemed to contain the group as modified, thus fulfilling the written description of all Markush groups used in the appended claims.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

Unless otherwise indicated, all numbers expressing a characteristic, item, quantity, parameter, property, term, and so forth used in the present specification and claims are to be understood as being modified in all instances by the term “about.” As used herein, the term “about” means that the characteristic, item, quantity, parameter, property, or term so qualified encompasses a range of plus or minus ten percent above and below the value of the stated characteristic, item, quantity, parameter, property, or term. Accordingly, unless indicated to the contrary, the numerical parameters set forth in the specification and attached claims are approximations that may vary. For instance, as mass spectrometry instruments can vary slightly in determining the mass of a given analyte, the term “about” in the context of the mass of an ion or the mass/charge ratio of an ion refers to +/−0.50 atomic mass unit. At the very least, and not as an attempt to limit the application of the doctrine of equivalents to the scope of the claims, each numerical indication should at least be construed in light of the number of reported significant digits and by applying ordinary rounding techniques.

Notwithstanding that the numerical ranges and values setting forth the broad scope of the invention are approximations, the numerical ranges and values set forth in the specific examples are reported as precisely as possible. Any numerical range or value, however, inherently contains certain errors necessarily resulting from the standard deviation found in their respective testing measurements. Recitation of numerical ranges of values herein is merely intended to serve as a shorthand method of referring individually to each separate numerical value falling within the range. Unless otherwise indicated herein, each individual value of a numerical range is incorporated into the present specification as if it were individually recited herein.

Use of the terms “may” or “can” in reference to an embodiment or aspect of an embodiment also carries with it the alternative meaning of “may not” or “cannot.” As such, if the present specification discloses that an embodiment or an aspect of an embodiment may be or can be included as part of the inventive subject matter, then the negative limitation or exclusionary proviso is also explicitly meant, meaning that an embodiment or an aspect of an embodiment may not be or cannot be included as part of the inventive subject matter. In a similar manner, use of the term “optionally” in reference to an embodiment or aspect of an embodiment means that such embodiment or aspect of the embodiment may be included as part of the inventive subject matter or may not be included as part of the inventive subject matter. Whether such a negative limitation or exclusionary proviso applies will be based on whether the negative limitation or exclusionary proviso is recited in the claimed subject matter.

The terms “a,” “an,” “the” and similar references used in the context of describing the present invention (especially in the context of the following claims) are to be construed to cover both the singular and the plural, unless otherwise indicated herein or clearly contradicted by context. Further, ordinal indicators—such as, e.g., “first,” “second,” “third,” etc.—for identified elements are used to distinguish between the elements, and do not indicate or imply a required or limited number of such elements, and do not indicate a particular position or order of such elements unless otherwise specifically stated. All methods described herein can be performed in any suitable order unless otherwise indicated herein or otherwise clearly contradicted by context. The use of any and all examples or exemplary language (e.g., “such as”) provided herein is intended merely to better illuminate the present invention and does not pose a limitation on the scope of the invention otherwise claimed. No language in the present specification should be construed as indicating any non-claimed element essential to the practice of the invention.

When used in the claims, whether as filed or added per amendment, the open-ended transitional term “comprising”, variations thereof such as, e.g., “comprise” and “comprises”, and equivalent open-ended transitional phrases thereof like “including,” “containing” and “having”, encompass all the expressly recited elements, limitations, steps, integers, and/or features alone or in combination with unrecited subject matter; the named elements, limitations, steps, integers, and/or features are essential, but other unnamed elements, limitations, steps, integers, and/or features may be added and still form a construct within the scope of the claim. Specific embodiments disclosed herein may be further limited in the claims using the closed-ended transitional phrases “consisting of” or “consisting essentially of” (or variations thereof such as, e.g., “consist of”, “consists of”, “consist essentially of”, and “consists essentially of”) in lieu of or as an amendment for “comprising.” When used in the claims, whether as filed or added per amendment, the closed-ended transitional phrase “consisting of” excludes any element, limitation, step, integer, or feature not expressly recited in the claims. The closed-ended transitional phrase “consisting essentially of” limits the scope of a claim to the expressly recited elements, limitations, steps, integers, and/or features and any other elements, limitations, steps, integers, and/or features that do not materially affect the basic and novel characteristic(s) of the claimed subject matter. Thus, the meaning of the open-ended transitional phrase “comprising” is being defined as encompassing all the specifically recited elements, limitations, steps and/or features as well as any optional, additional unspecified ones. The meaning of the closed-ended transitional phrase “consisting of” is being defined as only including those elements, limitations, steps, integers, and/or features specifically recited in the claim, whereas the meaning of the closed-ended transitional phrase “consisting essentially of” is being defined as only including those elements, limitations, steps, integers, and/or features specifically recited in the claim and those elements, limitations, steps, integers, and/or features that do not materially affect the basic and novel characteristic(s) of the claimed subject matter. Therefore, the open-ended transitional phrase “comprising” (and equivalent open-ended transitional phrases thereof) includes within its meaning, as a limiting case, claimed subject matter specified by the closed-ended transitional phrases “consisting of” or “consisting essentially of.” As such, the embodiments described herein or so claimed with the phrase “comprising” expressly and unambiguously provide description, enablement and support for the phrases “consisting essentially of” and “consisting of.”

Lastly, the terminology used herein is for the purpose of describing particular embodiments only and is not intended to limit the scope of the present invention, which is defined solely by the claims. Accordingly, the present invention is not limited to that precisely as shown and described.

What is claimed is:

1. A method of optimizing the responsiveness of a sensor or detector for interrogating a target material, the method comprising:
providing a transmit coil in communication with a receive coil, the transmit coil configured to emit an oscillating electromagnetic field and the receive coil receiving the electromagnetic field; and
adjusting the slope or rate of change of the capacitive reactance of the sensor circuit such that high rates of change in output signal of the receive coil is produced in response to differences in a target material.

2. The method of optimizing of claim 1 further comprising the steps of placing the receive coil in a location relative to a transmit coil optimizing the output signal.

3. The method of optimizing of claim 2 further comprising the steps of inducing an angle in the sensor relative to the target material, optimizing the output signal.

4. The method of optimizing of claim 2 further comprising the steps of adding a second receive coil and allowing the signals of the receive coils to be combined, optimizing the output signal.

5. The method of optimizing of claim 4 further comprising the steps of inducing an angle in the sensor relative to the target material, optimizing the output signal.

6. A method of optimizing the responsiveness of a sensor or detector for interrogating a target material, the method comprising:
providing a transmit coil in communication with a receive coil, the transmit coil configured to emit an oscillating electromagnetic field and the receive coil receiving the electromagnetic field; and
adjusting the slope or rate of change of the inductive reactance of the sensor circuit such that high rates of change in output signal of the receive coil is produced in response to differences in a target material.

7. The method of optimizing of claim 6 further comprising the steps of placing the receive coil in a location relative to a transmit coil optimizing the output signal.

8. The method of optimizing of claim 7 further comprising the steps of inducing an angle in the sensor relative to the target material, optimizing the output signal.

9. The method of optimizing of claim 7 further comprising the steps of adding a second receive coil and allowing the signals of the receive coils to be combined, optimizing the output signal.

10. The method of optimizing of claim 9 further comprising the steps of inducing an angle in the sensor relative to the target material, optimizing the output signal.

11. A method of optimizing the responsiveness of a sensor or detector for interrogating a target material, the method comprising:
providing a transmit coil in communication with a receive coil, the transmit coil configured to emit an oscillating electromagnetic field and the receive coil receiving the electromagnetic field; and
adjusting the slope or rate of change of the capacitive reactance and the inductive reactance of the sensor circuit such that high rates of change in output signal of the receive coil is produced in response to differences in a target material.

12. The method of optimizing a sensor of claim 11 further comprising the steps of placing the receive coil in a location relative to a transmit coil optimizing the output signal.

13. The method of optimizing of claim 12 further comprising the steps of inducing an angle in the sensor relative to the target material, optimizing the output signal.

14. The method of optimizing of claim 12 further comprising the steps of adding a second receive coil and allowing the signals of the receive coils to be combined, optimizing the output signal.

15. The method of optimizing of claim 14 further comprising the steps of inducing an angle in the sensor relative to the target material, optimizing the output signal.
